(19) United States
(12) Patent Application Publication
(10) Pub. No.: US 2014/0261634 A1
(43) Pub. Date: Sep. 18, 2014

(54) COMBINATION SOLAR THERMAL AND PHOTOVOLTAIC MODULE

(71) Applicant: FAFCO INCORPORATED, Chico, CA (US)

(72) Inventors: Michael R. RUBIO, Chico, CA (US); Alexander WARD, Chico, CA (US)

(73) Assignee: FAFCO INCORPORATED, Chico, CA (US)

(21) Appl. No.: 14/201,652

(22) Filed: Mar. 7, 2014

Related U.S. Application Data
(60) Provisional application No. 61/778,204, filed on Mar. 12, 2013.

(51) Int. Cl. H01L 31/0525; H05K 13/00

(52) U.S. Cl. CPC H01L 31/058; H05K 13/0023
USPC 136/248; 29/592.1

(57) ABSTRACT

An integrated solar thermal and photovoltaic apparatus. The apparatus includes a solar thermal module, and a photovoltaic module comprising a plurality of solar cells configured in a polymeric material. The apparatus has an amorphous material configured between the thermal solar module and the photovoltaic module. The amorphous material has a semi-viscous, thermally conductive, and mastic characteristic to allow for thermal expansion and contraction of either or both the photovoltaic module or the solar thermal module during an operating time. The apparatus has an aperture region provided on a first side of the photovoltaic module and the solar thermal module is overlying a second side of the photovoltaic module. The thermal solar module, the photovoltaic module, and the amorphous material form an integrated thermal solar module.

### CROSS-REFERENCE TO RELATED APPLICATIONS

This application claims priority to U.S. Ser. No. 61/778,204 (Attorney Docket No. A943R0-000100PV) filed Mar. 12, 2013, commonly assigned, and hereby incorporated by reference for all purposes.

### GOVERNMENT RIGHTS

This invention was made by support of the U.S. Government Alliance for Sustainable Energy, LLC Management and Operating Contractor For the National Renewable Energy Laboratory (“NREL”) under Subcontract No. AEU-2-22001-01, and the U.S. Government may have certain rights in this invention.

### BACKGROUND OF INVENTION

The present invention relates generally to solar energy techniques. More particularly, the present invention provides a method and apparatus for generating energy by way of a combination of photovoltaic and thermal solar conversion devices. Merely by way of example, the invention has been applied to a solar module, but it would be recognized that the invention has a much broader range of applicability.

As the population of the world explodes, industrial expansion has lead to an equally large consumption of energy. Energy often comes from fossil fuels, including coal and oil, hydroelectric plants, nuclear sources, and others. Almost every element of our daily lives depends, in part, on oil, which is becoming increasingly scarce. As time further progresses, an era of “cheap” and plentiful oil is coming to an end. Accordingly, other and alternative sources of energy have been developed. Unfortunately, other sources such as nuclear has lead to catastrophic events such as the 2011 Fukushima Daiichi nuclear disaster, Chernobyl disaster, among others.

Concurrent with oil, we have also relied upon other very useful sources of energy such as hydroelectric, nuclear, and the like to provide our electricity needs. As an example, most of our conventional electricity requirements for home and business use comes from turbines run on coal or other forms of fossil fuel, nuclear power generation plants, and hydroelectric plants, as well as other forms of renewable energy. Often times, home and business use of electrical power has been stable and widespread.

Most importantly, much if not all of the useful energy found on the Earth comes from our sun. Generally all common plant life on the Earth achieves life using photosynthesis processes from sunlight. Fossil fuels such as oil were also developed from biological materials derived from energy associated with the sun. For human beings including “sun worshipers,” sunlight has been essential. For life on the planet Earth, the sun has been our most important energy source and fuel for modern day solar energy.

Solar energy possesses many characteristics that are very desirable! Solar energy is renewable, clean, abundant, and often widespread. Certain technologies developed often capture solar energy, concentrate it, store it, and convert it into other useful forms of energy.

Solar panels have been developed to convert sunlight into energy. As merely an example, solar thermal panels often convert electromagnetic radiation from the sun into thermal energy for heating homes, running certain industrial processes, or driving high grade turbines to generate electricity. As another example, solar photovoltaic panels convert sunlight directly into electricity for a variety of applications. Solar panels are generally composed of an array of solar cells, which are interconnected to each other. The cells are often arranged in series and/or parallel groups of cells in series. Accordingly, solar panels have great potential to benefit our nation, security, and human users. They can even diversify our energy requirements and reduce the world's dependence on oil and other potentially detrimental sources of energy.

Although solar panels have been used successful for certain applications, there are still certain limitations. Solar cells are often costly. Depending upon the geographic region, there are often financial subsidies from governmental entities for purchasing solar panels, which often cannot compete with the direct purchase of electricity from public power companies. Additionally, the panels are often composed of silicon bearing wafer materials. Such wafer materials are often costly and difficult to manufacture efficiently on a large scale. Availability of solar panels is also somewhat scarce. That is, solar panels are often difficult to find and purchase from limited sources of photovoltaic silicon bearing materials. These and other limitations are described throughout the present specification, and may be described in more detail below.

### SUMMARY OF INVENTION

According to the present invention, techniques related to solar energy are provided. More particularly, the present invention provides a method and apparatus for generating energy by way of a combination of photovoltaic and thermal solar conversion devices. Merely by way of example, the invention has been applied to a solar module, but it would be recognized that the invention has a much broader range of applicability.

In an example, the present invention provides an integrated solar thermal and photovoltaic apparatus. The apparatus includes a solar thermal module, and a photovoltaic module comprising a plurality of solar cells configured in a polymeric material. The apparatus has an amorphous material configured between the thermal solar module (including tubes) and the photovoltaic module. The amorphous material has a semi-viscous, thermally conductive, and mastic characteristic to allow for thermal expansion and contraction of either or both the photovoltaic module or the solar thermal module during an operating time. The apparatus has an aperture region provided on a first side of the photovoltaic module and the solar thermal module is overlying a second side of the photovoltaic module. The thermal solar module, the photovoltaic module, and the amorphous material form an integrated thermal solar module. In an example, the thermal solar module is free from a frame assembly and comprises exposed edges.

As shown is a method of assembling an integrated solar thermal and photovoltaic apparatus. As noted, the method includes providing a solar thermal module having a flexible characteristic. The method includes providing a photovoltaic module comprising a plurality of solar cells configured in a polymeric material. The photovoltaic module has an aperture region and a backside region. The method includes forming an amorphous material overlying the backside region, and aligning a first end of the thermal solar module onto a first end of the photovoltaic module, as shown.

In an example, the method also includes pressing the first end of the thermal solar module with the first end of the photovoltaic module and sandwiching the amorphous material from the first end of the first end and the photovoltaic module. The method continues to press of the thermal solar module using a rolling action as an interface between a portion of the thermal solar module and a portion of the amorphous material moves from a first end to a second end while causing the thermal solar module to be disposed against the amorphous material substantially free from any gas bubbles between the thermal solar module and the amorphous material or free from any other imperfections. The method forms an integrated thermal solar module and photovoltaic module having the amorphous material there between and characterized as a semi-viscous, thermally conductive, and mastic characteristic to allow for thermal expansion and contraction of either or both the photovoltaic module or the solar thermal module during an operating time. Preferably, the amorphous material remains in a fluidic state, which allows the amorphous material to slide and move freely between the two modules, although there can be variations.

In an example, the present techniques provide a rigid combination solar thermal and photovoltaic module that transfers solar heat to a fluid and simultaneously cools the photovoltaic component providing improved electrical performance while simultaneously providing 3-5× thermal energy. The solar module is comprised of a photovoltaic and solar thermal component. That is, the module comprises a single module, joined by an amorphous material, and mounting hardware. The present techniques provide an amorphous material that eliminates the need for high tensile adhesion between the photovoltaic module and solar thermal panel. This is accomplished by transferring the loads to a mechanical structure comprised of longitudinal and transverse members, which conventional modules have consistently failed to accommodate differential coefficient of thermal expansion (CTE) over the life of the product. In an example, the module also withstands high wind load with minimal roof penetrations, enables low cost installations, is lightweight, and corrosion resistant. Typical applications include providing solar electricity while heating fluid for swimming pools, process heating, heat pumps, domestic heating, commercial and industrial heating. Of course, there are other examples.

In an example, the present techniques use an amorphous material having a fluidic characteristic. In an example, the characteristics include at least one or more of the following:

a) High surface tension
i) Enables dispersive adhesion of the material to various substrates

b) High viscosity
i) Enables the material to have sufficient double slump properties
ii) Material's viscosity is such that dynamic viscosity does not directly apply
iii) Comparable viscosities: peanut butter or modeling clay

c) Zero water content
i) Allows the material to maintain stability over a long period of time by avoiding evaporative losses

d) High thermal conductivity
i) Allows the mastic to transfer direct heat from the PV module to the Solar Thermal Absorber underneath. Values in excess of 0.6 joule/(m)(s)(Degree K)

e) Thermally stable in homogeneity
i) Material does not separate in high heat over long dwell periods
ii) Specifics: 85 C in excess of 168 hours continuously

f) Low volatile content
i) Must maintain greater that 98% solids by weight over 168 continuous hours at 85 C

g) Weather Resistant
i) Testing concludes that the material is minimally affected by continued exposure to damp heat (85% Relative Humidity at 85 C) in designed exposure cases.

Many benefits are achieved by way of the present invention over conventional embodiments and techniques. These implementations provide several means of maintaining or improving photovoltaic conversion efficiency and reliability, which can be tailored depending on various requirements of specific applications. These and other benefits are described throughout the present specification and more particularly below.

Various additional objects, features and advantages of the present invention can be more fully appreciated with reference to the detailed description and accompanying drawings that follow.

### BRIEF DESCRIPTION OF THE DRAWINGS

In order to more fully understand the present invention, reference is made to the accompanying drawings. Understanding that these drawings are not to be considered limitations in the scope of the invention, the presently described embodiments and the presently understood best mode of the invention are described with additional detail through use of the accompanying drawings in which:

FIG. 1 is a simplified diagram illustrating a manufacturing flow for the manufacture of the thermal solar module according to an embodiment of the present invention.

FIG. 2 illustrates a simplified diagram of stringing a plurality of silicon solar cells (upper) and a simplified diagram of a photovoltaic module including front and back sheets, a plurality of solar cells sandwiched between EVA, a stiffener, and adhesive material to form the photovoltaic module.

FIG. 3 illustrates a process of laminating the photovoltaic module according to an embodiment of the present invention.

FIG. 4 depicts an assembly of a junction box and connectors to the photovoltaic module according to an embodiment of the present invention.

FIG. 5 is a simplified diagram illustrating a thermal solar module configured with a pair of manifolds according to an embodiment of the present invention.

FIG. 6 is a simplified top view diagram of work-stations according to embodiments of the present invention.

FIG. 7 is a simplified diagram illustrating a coating process of an amorphous material overlying a photovoltaic module according to an embodiment of the present invention.

FIG. 8 is a simplified diagram illustrating a smoothing or leveling process according to an embodiment of the present invention.

FIG. 9 is a process of aligning a module onto a fixture station according to an embodiment of the present invention.

FIG. 10 is a simplified diagram illustrating a framing process of a module according to an embodiment of the present invention.

FIGS. 11-14 are simplified diagrams of configuring, including aligning, and rolling, a thermal solar module comprising the amorphous material with a photovoltaic module according to an embodiment of the present invention.

FIG. 15 is a simplified diagram of attaching struts and header supports to the sandwiched photovoltaic module and thermal solar module according to an embodiment of the present invention.

FIGS. 16-20 are simplified illustrations of a thermal solar module according to an embodiment of the present invention.

FIG. 21 is a simplified diagram of a photograph of a completed thermal and photovoltaic module according to an embodiment of the present invention.

FIG. 22 is an illustration of a top view of the completed thermal and photovoltaic module according to an embodiment of the present invention.

FIG. 23 is a perspective view of the completed thermal and photovoltaic module according to an embodiment of the present invention.

### DESCRIPTION OF THE SPECIFIC EMBODIMENTS

According to the present invention, techniques related to solar energy are provided. More particularly, the present invention provides a method and apparatus for generating energy by way of a combination of photovoltaic and thermal solar conversion devices. Merely by way of example, the invention has been applied to a solar module, but it would be recognized that the invention has a much broader range of applicability. Further details of the present invention can be found throughout the present specification and more particularly below.

Solar technologies have historically suffered from low efficiencies and high cost. Billions of dollars in research and development have been spent to reduce photovoltaic (PV) module and system costs, but the installed price still does not yield attractive paybacks or leveled cost of energy for the consumer. Solar thermal systems also once suffered from low efficiencies and high costs primarily because designs were focused on yielding excessively high temperatures, which are only necessary for a limited number of applications such as re-circulating process heat applications.

In the early 1970's, a pioneering technique providing a low cost, highly efficient polymer solar thermal collector was introduced by FAFCO, INC, present assignee, and described in U.S. Pat. No. 3,934,323, commonly assigned and hereby incorporated by reference herein. This technique enabled a new class of highly efficient, low cost solar thermal systems, which are still sold today for heating swimming pools and preheating hot water systems. This unglazed collector design accounts for the majority of solar thermal installations in the United States, over 20 GW of thermal output worldwide, 5 GW directly produced by FAFCO solar collectors representing 10% of the renewable energy worldwide (Source: IEA).

In an example, the present techniques combine the low cost, high efficient polymer solar thermal collector by “fusing” it to a custom state-of-the-art polymer crystalline photovoltaic module. This combination solar thermal and photovoltaic module produces three to five times more energy per square foot versus photovoltaic alone. The large 40 square foot collector provides 500 watts of electrical power plus another 1500 watts of thermal power for a total of 2000 watts per collector or 50 watts per square foot. The collector design is a combination of a low cost highly efficient polymer solar thermal collector and a custom innovative polymer crystalline photovoltaic module. An amorphous material thermally and structurally mates the two together. The thermal bonding enables high efficient solar thermal performance while cooling the photovoltaic module, which improves electrical output. Stand alone photovoltaic modules heat up in the sunlight, which substantially decreases electrical output. At a typical dimension of 4 feet wide×10 feet long, it is one of the largest single photovoltaic-based collectors on the market. Many residential photovoltaic systems have nominal outputs of 2000 watts. A single ultra high power density collector will output as much in combined electrical and thermal output.

In example, commercial applications include large hot water users such as convalescent homes, military barracks, dormitories, schools, hotels/motels, apartments, laundry-mats, industrial plants, prisons, hospitals, vacation resorts, health clubs, food processing plants, residential subdivisions, and more. This technology has many benefits including more cost effective renewable energy options, better utilization of roof space with higher efficient solar energy conversion, supports government goals and policies on clean energy, provides new jobs, offsets fossil fuel use, and reduces dependence upon foreign energy sources. Of course, there can be variations.

As further background, we discovered that conventional combination solar thermal and photovoltaic module have been plagued without success because of at least one or more of the following reasons:

High cost due to a focus on high temperature solar thermal and concentrating technologies which constrain designs to expensive materials. This also leads to overheating issues that must be overcome with additional expensive hardware. See, for example, Cogenra Solar (US 2010/0319684).

Small-scale designs utilize expensive metal suffer from excessive connections and low performance due to the small aperture to gross area ratio. See, for example, SunDrum Solar (US 2009/0084430).

Failure to accommodate differential thermal expansion over the life of the product. The most notable attempt was by Powerlight Corporation's Photovoltaic-Thermal Hybrid Commercial Roofing System (See, for example, U.S. Pat. No. 6,675,580 B2). This approach was unsuccessful:
1. Could not overcome the technical challenge of thermally mating solar thermal collector and PV module without delamination due to large differences in material coefficients of thermal expansion; and
2. Over-constrained the design by requiring the product to be roll-able, which increases the challenge of preventing delamination.

Of course, there can be other limitations. These and other limitations of conventional technique are overcome by the present techniques, which have been described in more detail throughout the present specification and more particularly below.

In a specific embodiment, the present invention provides the following techniques, which are briefly outlined below and can be referenced by FIGS. 1 through 15.

### Framing the PV Module

Place PV on Frame Table

Trim edges if necessary to ensure an optimal fit

Test fit frame and confirm fixture alignment

Remove frame

Flame treat the front sheet of the PV module

IPA wipe front sheet

IPA wipe aluminum

Dyne test front sheet to confirm surface energy is ˜50 dynes

Using a hot melt pail un-loader, apply ˜¼″ bead of adhesive to the left length of the PV Module

Apply left edge rail and immediate clamp

Repeat for right edge

Repeat for upper and lower cross members, respectively

Insert sheet metal screws in pre-drilled corner holes

Wait ˜2 min or until sufficiently cool (less than 100 F)

Remove clamps

Remove panel and progress onto Rolling Table

As shown, the present method has a sequence of steps, which can be varied, modified, replaced, reordered, expanded, contracted, or any combinations thereof. That is, the method repeats any of the above steps. Such steps may be performed alone or in combination with others, which are described or not even described. The steps can be performed in the order shown or in other orders, if desired. The steps also can be performed using a combination of conventional processing and assembly techniques. The steps also can be performed using hardware or other processes implemented using software and the like. Of course, there can be many other variations, modifications, and alternatives. Further details of the present method can be found throughout the present specification and more particularly below.

### Apply Amorphous Material

Set screed to beginning position

Insert solar thermal absorber and align to edge

Clamp upper header

Clamp lower header

Use drawbar to pull absorber taut.

Pump amorphous material onto the plane of the solar thermal absorber the width of the absorber and 1 foot in length

Pull the screed down the length of the absorber along the linear bearings until amorphous material ceases to be moved

Pull screed back ˜2″ before amorphous material ceases to be consistent

Repeat pumping process and screeding until the length of the module is substantially covered by the amorphous material

Pump more material onto any low spots or voids in the plane of the amorphous material

Lift the screed above the plane of the amorphous material and set to beginning position

Clear screed of any excessive amorphous material

Pull screed the full length of the absorber to smooth out any additional material

Repeat from step 7

Inspect plane of amorphous material to ensure minimal irregularities including voids, debris and air pockets.

Repeat from step 7 if necessary.

Loosen draw bar and remove clamps

Prepare to progress to rolling table.

As shown, the present method has a sequence of steps, which can be varied, modified, replaced, reordered, expanded, contracted, or any combinations thereof. That is, the method repeats any of the above steps. Such steps may be performed alone or in combination with others, which are described or not even described. The steps can be performed in the order shown or in other orders, if desired. The steps also can be performed using a combination of conventional processing and assembly techniques. The steps also can be performed using hardware or other processes implemented using software and the like. Of course, there can be many other variations, modifications, and alternatives. Further details of the present method can be found throughout the present specification and more particularly below.

### Rolling Table Process

Place framed PV module face-down on Rolling Table.

Fit electrical leads into relief holes and junction boxes into relief pockets

Align end of module to the end of the Edge Rail Guides

Ensure that the Edge Rails are completely contacting the respective surface

Position the Solar Thermal Absorber face-up over the rolling device

Clamp absorber headers into position ensuring alignment is correct

Install hoist cable onto opposing header

Begin to lift solar thermal absorber until vertical

Slowly move along the length of the rolling table, inverting the solar thermal absorber so that the mastic material faces the back sheet of the PV module.

Once the first ˜1 ft of absorber is in contact with the PV module, move the rolling device into position above the backside of the solar thermal absorber.

Lower the roller slowly and engage air pressure

Pull the rolling device along the length of the rolling table, guided by the linear bearings, lowering the solar thermal absorber, maintaining contact only at the interface at the tangent point where the roller is applying the required force.

When complete, lift roller above the plane of the solar thermal absorber and pull back to the starting position.

Slide Strut Covers over the Aluminum Struts

Insert the Aluminum Strut/Cover assembly into the Edge Rails.

Align screw holes and fasten with sheet metal screws.

Remove composite module from fixture and flip along the width so that the solar cells are face-up.

Install the Upper Header Supports by sliding them over the header

Locate pre-drilled holes and fasten with sheet metal screws.

Repeat steps 18 and 19 for Lower Header Supports

Inspect for Quality Assurance

The composite Photovoltaic/Solar Thermal is complete (PVT or FAFCO Fusion by FABCO INCORPORATED)

As shown, the present method has a sequence of steps, which can be varied, modified, replaced, reordered, expanded, contracted, or any combinations thereof. That is, the method repeats any of the above steps. Such steps may be performed alone or in combination with others, which are described or not even described. The steps can be performed in the order shown or in other orders, if desired. The steps also can be performed using a combination of conventional processing and assembly techniques. The steps also can be performed using hardware or other processes implemented using software and the like. Of course, there can be many other variations, modifications, and alternatives. Further details of the present method can be found throughout the present specification and more particularly below.

FIG. 1 is a simplified diagram illustrating a manufacturing flow for the manufacture of the thermal solar module according to an embodiment of the present invention.

FIG. 2 illustrates a simplified diagram of stringing a plurality of silicon solar cells (upper) and a simplified diagram of a photovoltaic module including front and back sheets, a plurality of solar cells sandwiched between EVA, a stiffener, and adhesive material to form the photovoltaic module. In an example, the plurality of solar cells are electrically strung together in series such that no interconnects interfere with a lengthwise thermal expansion of the photovoltaic module. In an example, the plurality of solar cells are electrically strung together in series such that a resulting maximum power voltage ranges from 90 to 110 volts.

FIG. 3 illustrates a process of laminating the photovoltaic module according to an embodiment of the present invention. In an example, the module includes a polymeric material that comprises ETFE, EVA, PET, and EVA. Of course, there can be variations.

FIG. 4 depicts an assembly of a junction box and connectors to the photovoltaic module according to an embodiment of the present invention.

FIG. 5 is a simplified diagram illustrating a thermal solar module configured with a pair of manifolds according to an embodiment of the present invention.

FIG. 6 is a simplified top view diagram of workstations according to embodiments of the present invention. As shown, each of the workstations is provided for processing the manufacture and assembly of the thermal solar module according to an embodiment of the present invention.

FIG. 7 is a simplified diagram illustrating a coating process of an amorphous material overlying a photovoltaic module according to an embodiment of the present invention. As shown, the photovoltaic module is coated using a material configured to engage the photovoltaic module with the thermal module. That is, the amorphous material is dispensed in a fluidic state overlying the backside region and smoothing a surface region of the amorphous material using a mechanical blade member, as noted below.

In an example, the material provides a thermal interface between the photovoltaic module and the solar thermal absorber. In an example, the material is characterized as a colloidal semi-fluid, which remains in a fluidic state while configured between the panels. Wherein “colloidal” is defined as many particles thoroughly dispersed in a fluidic material and “semi-fluid” is defined as a substance that appears solid though capable of flowing under stress. Henceforth the term “material” will refer to the thermal interface colloidal semi-fluid substance. The colloidal mixture is primarily composed of calcium carbonate, petroleum oil, clay, stabilizers and surfactants. Of course, there can be other variations.

In an example, the material can come from a source, e.g., pail or other container. The material is then pumped from bulk pails via a bulk applicator, which is an air-driven positive displacement piston-type pump. The pump flows the material through a hose system with distributes the material over the plane of the solar thermal absorber. The material is applied at room temperature. The internal pressure of the pumped material can be in excess of 5000 pounds per square inch. In an example, the operating temperature range of the composite module is 0 to 200 F, although there can be other temperatures. In an example, parameters can be found throughout the present specification and more particularly below:

Bulk application capable of 5-10 pounds/minute with ⅛″ nozzle applying of a bead resulting in a minimum 1″ wide interface no more than 0.040″ thick of 20-30 psi adhesive between photovoltaic module and frame enabling substantial wind resistance;

Bulk applicator capable of 5-10 pounds/minute to quickly apply large drums of mastic; and

Precise screed during mastic application and uniform controlled rolling of solar thermal collector with mastic onto frame photovoltaic module, which maintains mastic thickness between 0.060″-0.120″ (to effectively maintain contact between the substrates, enable optimum heat transfer, and promote unconstrained thermal expansion).

In an example, the present material can be one sold under Product ED0227, Named as Sealer, and listed as 824084PM by H.B. Fuller Company, 1200 Willow Lake Boulevard Vadnais Heights, Minn. 55110. In an example, the Sealer is listed in Exhibit 1, which is incorporated by reference herein.

In an example, the amorphous material is characterized by high thermal stability and resistance to separation as proven by over 168 hours at 85 degrees-Celsius, low volatile content maintaining greater than 98% solids by weight over 168 continuous hours at 85 degrees-Celsius, weather resistant as proven by exposure to damp heat at 85% relative humidity and 85 degrees-Celsius, high thermal conductivity with values in excess of 0.6 joule/(m)(s)(Degree K), and a high surface tension and viscosity as proven by a slump test with 2 inch diameter sample pressed against a vertically oriented plate wherein the sample falls less than ⅜ inch over 30 minute period. In an example, the amorphous material comprises a non-volatile hydrocarbon entity, a plurality of particles, and a plurality of surfactants to cause the thickness of material to be substantially homogeneous. In an example, the amorphous material is provided for an operating time is provided of at least twenty years or more without delamination or other failure mode.

FIG. 8 is a simplified diagram illustrating a smoothing or leveling process according to an embodiment of the present invention. In an example, the method includes forming of the amorphous material comprises dispensing the amorphous material in a fluidic state overlying the backside region and smoothing a surface region of the amorphous material using a mechanical blade member such that a thickness of the amorphous material is substantially uniform from the first end to the second end. As shown, the present technique forms the substantially uniform surface region and thickness from end to end and throughout an entirety of the amorphous material.

FIG. 9 is a process of aligning a module onto a fixture station according to an embodiment of the present invention. Here, the module is aligned in the fixture station.

FIG. 10 is a simplified diagram illustrating a framing process of a module according to an embodiment of the present invention. In an example, the module is configured to the frame, as shown.

FIGS. 11-14 are simplified diagrams of configuring, including aligning, and rolling, a thermal solar module comprising the amorphous material with a photovoltaic module according to an embodiment of the present invention. As shown is a method of assembling an integrated solar thermal and photovoltaic apparatus, and more particularly to the alignment, rolling and attachment process. As noted, the method includes providing a solar thermal module having a flexible characteristic. The method includes providing a photovoltaic module comprising a plurality of solar cells configured in a polymeric material. The photovoltaic module has an aperture region and a backside region. The method includes forming an amorphous material overlying the backside region, and aligning a first end of the thermal solar module onto a first end of the photovoltaic module, as shown.

In an example, the method also includes pressing the first end of the thermal solar module with the first end of the photovoltaic module and sandwiching the amorphous material from the first end of the first end and the photovoltaic module. As shown, the method continues to press of the thermal solar module using a rolling action as an interface between a portion of the thermal solar module and a portion of the amorphous material moves from a first end to a second end while causing the thermal solar module to be disposed against the amorphous material substantially free from any gas bubbles between the thermal solar module and the amorphous material or free from any other imperfections.

As shown, the method forms an integrated thermal solar module and photovoltaic module having the amorphous material there between and characterized as a semi-viscous, thermally conductive, and mastic characteristic to allow for thermal expansion and contraction of either or both the photovoltaic module or the solar thermal module during an operating time. Preferably, the amorphous material remains in a fluidic state, which allows the amorphous material to slide and move freely between the two modules, although there can be variations. In an example, the method also includes subjecting the sandwiched structure to a rolling process from the first end to the second end. In an example, the photovoltaic module is maintained in a flat and stationary position during the pressing and continuing pressing process.

FIG. 15 is a simplified diagram of attaching struts and header supports to the sandwiched photovoltaic module and thermal solar module according to an embodiment of the present invention. As shown, the method also includes configuring a frame to the photovoltaic module, and preferably configuring a plurality of struts to the integrated thermal solar module. Further details of the completed integrated thermal solar module can be found throughout the present specification and more particularly below.

FIGS. 16-20 are simplified illustrations of a thermal solar module according to an embodiment of the present invention. As shown are the various views, including perspective, exploded, top and bottom views, and side views according to examples. The module also includes (1) edge trim, (2) cross-bar, (3) header support; (4) T bar support; (5) T bar cover; (6) screws, (7) screws, (8) header support, (9) PV Module, (10) thermal panel, (11) panel clips, (12) thermal mastic, and (13) edge trim adhesive. Of course, there can be variations.

FIG. 21 is a simplified diagram of a photograph of a completed thermal and photovoltaic module according to an embodiment of the present invention. As shown is a completed, fully functional, thermal and photovoltaic module. Further details of the module can be found throughout the present specification and more particularly below.

FIG. 22 is an illustration of a top view of the completed thermal and photovoltaic module according to an embodiment of the present invention. As shown, the top view is transparent and allows for a visual pattern within the aperture region of the module. Also shown are the headers, and struts, according to an example. Of course, there can be variations.

FIG. 23 is a perspective view of the completed thermal and photovoltaic module according to an embodiment of the present invention. As shown, the top view is transparent and allows for a visual pattern within the aperture region of the module. Also shown are the headers, and struts, according to an example. Of course, there can be variations.

In an example, the module has a frame assembly and the thermal solar module comprises an adhesive material configured to exceed 30 pounds per square inch in shear strength over a twenty year operation life. In an example, the thermal solar module photovoltaic module has a width of forty-eight inches and greater and a width length of one hundred inches and greater. In an example, the thermal solar module photovoltaic module has a weight of 0.5 pounds per square foot and less. In an example, a frame assembly is configured to the integrated thermal solar module with a unique attribute of elevation above the roof structure, mounting to all common roof structures, minimal roof penetrations, aligning to standard structural members, avoiding debris accumulation, providing for a high degree of movement to prevent damage caused by constrained thermal expansion. In an example, a frame assembly configured to the integrated thermal solar module. Further details of the present module can be found throughout the present specification and more particularly below.

### EXAMPLE

To prove the operation of the present invention, experiments were performed in one or more examples. These are merely examples, which should not unduly limit the scope of the claims herein. One of ordinary skill in the art would recognize other variations, modifications, and alternatives. In an example under subcontract No. AEU-2-22001-01, Integrated PV/Thermal System for Naval Base Guam, to support a partnership between the U.S. Navy's Naval Facilities Engineering Command (NAVFAC) and the National Renewable Energy Laboratory (NREL) to demonstrate leading-edge, cost-effective commercial energy technologies that can enable the Department of Defense (DoD) to meet its renewable energy goals and enhance its installation energy security.

In an example, a demonstration FAFCO integrated photovoltaic (PV)/thermal system, capable of 7-15 W/ft2 DC power generation at one sun (1,000 W/m2), 45-60 W/ft2 thermal power generation at one sun, and an estimated energy savings of roughly 85 MWh per year, will be provided to the Sierra Wharf Laundromat Building 1988 at the Joint Region Marianas (JRM) naval base in Guam.

In an example, substantial progress on the Integrated PV/Thermal System was made. We have prepared:

Fusion collector fabrication;

Collector test equipment fabrication;

Pump/HX skid and control module fabrication;

Header welder fabrication; and

Fusion collector fabrication.

In an example, we have successfully fabricated an integrated thermal solar collector (See FIGS. 21 and 22). In an example, certain processes have been used to produce the solar collector. Such processes include photovoltaic module fabrication, application of thermal mastic to solar thermal absorber, adhering the photovoltaic module to the outer aluminum frame with hot melt urethane adhesive, assembling the solar thermal absorber with thermal mastic to the framed photovoltaic module and completing the frame assembly.

In an example, the processes also included collector test equipment fabrication. The test process included testing preparations to assess thermal/electrical performance and wind load resistance of the thermal solar collector. In an example, we have provided a performance-tracking roof that includes recalibrated instrumentation. One the right of the tracking roof is the performance monitoring room. In an example, we tracked the I-V curve module output that is a 120V/120 A/600 W programmable DC electronic load. A 150V/10 A/1500 W DC power supply was provided to enable pinpointing any damage to cells caused by shipping or solar collector fabrication.

In an example, the wind load resistance-testing device is also proposed. In an example, the bottom has multiple suction cups that affix to the top surface of the solar collector. In an example, the top has multiple air cylinders that will simulate the uplift and down-force specified by the structural engineer. In an example, the pump/skid and control module has been included.

In conclusion, we demonstrated solar collector fabrication, collector test equipment fabrication, pump/HX skid and control module fabrication, and header welder fabrication. Of course, there can be variations.

In an example, the photovoltaic module itself is substantially flexible as proven by testing that rolled it into a ten (10) inch diameter cylinder with no measureable performance damage. The photovoltaic module can be effectively used as stand-alone to output electrical power, but cannot output useable heat, which is enabled by the combination with solar thermal absorber. In this flexible form, the module can be mounted directly upon a flat surface such as roof sheathing or conformed around a surface with a diameter of 10 inches or more. This allows the module to become integrated into the roof or mounting surface.

The combination solar thermal and photovoltaic module can also be created without the frame. In this configuration, a solar thermal—photovoltaic interface material is used that either constrains the coefficient of thermal expansion of the entire assembly or allows it repetitively expand and contract dynamically over the life of the assembly. In the version where the coefficient of thermal expansion is constrained, a cross linked material is used as the interface material. Cross-linking can be performed during the lamination process that fuses the photovoltaic module layers together.

When the photovoltaic module is framed, it becomes less flexible and semi-rigid. The advantage of this configuration is that it enables this large format module to be mounted above a non-flat surface such as common roof material (asphalt shingles, tile, rack, etc.). Elevating the module above the roof surface, rather mounting directly flush to the roof surface promotes roof material longevity and prevents the module from deforming around irregular roof material surfaces. The integrity of this framed version with its integrated mounting hardware has been tested to withstand over wind speeds up to 155 mph, although there can be variations. The framed version can be used with and without the solar thermal collector.

In an alternative example, the combination solar thermal and photovoltaic module can also be used with copper indium gallium selenide (CIGS) or other types of non-glass photovoltaic modules. In these configurations, the photovoltaic module fabrication process is external to the combination solar thermal and photovoltaic module production process. The utilization of alternate photovoltaic modules enables the combination solar thermal and photovoltaic module to be used with any number of commercially available photovoltaic modules.

Various example embodiments as described with reference to the accompanying drawings, in which embodiments have been shown. This inventive concept may, however, be embodied in many different forms and should not be construed as limited to the embodiments set forth herein. Rather, these embodiments are provided so that this disclosure is thorough and complete, and has fully conveyed the scope of the inventive concept to those skilled in the art. Like reference numerals refer to like elements throughout this application.

It has been understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the inventive concept. As used herein, the term “and/or” includes any and all combinations of one or more of the associated listed items.

It has be understood that when an element is referred to as being “connected” or “coupled” to another element, it can be directly connected or coupled to the other element or intervening elements may be present. In contrast, when an element is referred to as being “directly connected” or “directly coupled” to another element, there may be no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the inventive concept. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other.

Unless otherwise defined, all terms (including technical and scientific terms) used herein have the same meaning as commonly understood by one of ordinary skill in the art to which this inventive concept belongs. It has been be further understood that terms, such as those defined in commonly used dictionaries, should be interpreted as having a meaning that is consistent with their meaning in the context of the relevant art and will not be interpreted in an idealized or overly formal sense unless expressly so defined herein.

It should be understood that the description recited above is an example of the disclosure and that modifications and changes to the examples may be undertaken which are within the scope of the claimed disclosure. Therefore, the scope of the appended claims should be accorded the broadest interpretation so as to encompass all such modifications and similar arrangements, including a full scope of equivalents.

1. An integrated solar thermal apparatus, the apparatus comprising:
a first thickness of polymeric material;
a photovoltaic region comprising a plurality of photovoltaic cells spatially disposed within the photovoltaic region, the photovoltaic region overlying the first thickness of polymeric material;
a second thickness of polymeric material overlying the photovoltaic region to form a sandwiched structure including at least the first thickness of polymeric material, the photovoltaic region, and the second thickness of photovoltaic material;
a thermal solar module formed overlying the sandwiched structure;
a thickness of material disposed between the thermal solar module and the sandwiched structure, the thickness of material being characterized by a fluidic, viscous, and thermally conductive amorphous structure to allow for a thermal expansion and a thermal construction of either or both the thermal solar module and/or the sandwiched structure during operation while mechanically coupling the thermal solar module to the sandwiched structure; and
whereupon the sandwiched structure, the thickness of material, and the thermal solar module form an integrated thermal solar module.

2. Apparatus of claim 1 further comprising a plurality of tubes configured within the thermal solar module; wherein the thickness of material is characterized by a surface tension, a coefficient of friction, a resistance to separation, and is substantially permeable; wherein the operation is provided of at least twenty years or more.

3. Apparatus of claim 1 wherein the thickness of material comprises a non-volatile hydrocarbon entity, a plurality of particles, and a plurality of surfactants to cause the thickness of material to be substantially homogeneous; wherein the frame assembly and the thermal solar module comprises an adhesive material configured to exceeds 30 pounds per square inch in shear strength over a twenty year operation life.

4. Apparatus of claim 1 wherein the thermal solar module is free from a frame assembly; wherein the thermal solar module has a width of forty eight inches and greater and a width of one hundred inches and greater; wherein the thermal solar module has a weight of 0.5 pounds per square foot and less.

5. Apparatus of claim 1 wherein the plurality of solar cells are electrically strung together in series such that no interconnects interfere with a lengthwise thermal expansion of the photovoltaic module or wherein the plurality of solar cells are electrically strung together in series such that a resulting maximum power voltage ranges from 90 to 110 volts.

6. Apparatus of claim 1 wherein the first thickness of polymeric material comprises ETFE, EVA, PET-EVA-PET, and EVA; and wherein the second thickness of polymeric material comprises EVA and PET-EVA-PET; and further comprising a frame assembly configured to the integrated thermal solar module.

7. A method for assembling an integrated solar thermal apparatus, the method comprising:
forming a sandwiched structure configured as a solar module comprising a first thickness of polymeric material, a photovoltaic region comprising a plurality of photovoltaic cells spatially disposed within the photovoltaic region, the photovoltaic region overlying the first thickness of polymeric material, and a second thickness of polymeric material overlying the photovoltaic region to form the sandwiched structure including at least the first thickness of polymeric material, the photovoltaic region, and the second thickness of photovoltaic material;
a thermal solar module formed overlying the sandwiched structure;
forming a thickness of material disposed between the thermal solar module and the sandwiched structure, the thickness of material being characterized by a fluidic, viscous, and thermally conductive amorphous structure to allow for a thermal expansion and a thermal construction of either or both the thermal solar module and/or the sandwiched structure during operation while mechanically coupling the thermal solar module to the sandwiched structure; and
whereupon the sandwiched structure, the thickness of material, and the thermal solar module form an integrated thermal solar module.

8. Method of claim 7 further comprising a plurality of tubes configured within the thermal solar module; wherein the thickness of material is characterized by a surface tension, a coefficient of friction, a resistance to separation, and is substantially permeable; wherein the operation is provided of at least twenty years or more.

9. Method of claim 7 wherein the thickness of material comprises a non-volatile hydrocarbon entity, a plurality of particles, and a plurality of surfactants to cause the thickness of material to be substantially homogeneous.

10. Method of claim 7 the frame assembly and the thermal solar module comprises an adhesive material configured to exceeds 30 pounds per square inch in shear strength over a twenty year operation life; wherein the thermal solar module is free from a frame assembly; wherein the thermal solar module has a width of forty eight inches and greater and a width of one hundred inches and greater.

11. Method of claim 7 wherein the thermal solar module has a weight of 0.5 pounds per square foot and less.

12. Method of claim 7 wherein the plurality of solar cells are electrically strung together in series such that no interconnects interfere with a lengthwise thermal expansion of the photovoltaic module; or wherein the plurality of solar cells are electrically strung together in series such that a resulting maximum power voltage ranges from 90 to 110 volts.

13. Method of claim 7 wherein the first thickness of polymeric material comprises ETFE, EVA, PET-EVA-PET, and EVA; and wherein the second thickness of polymeric material comprises EVA and PET-EVA-PET; and further comprising a frame assembly configured to the integrated thermal solar module.

14. An integrated solar thermal and photovoltaic apparatus, the apparatus comprising:
a solar thermal module;
a photovoltaic module comprising a plurality of solar cells configured in a polymeric material;
an amorphous material configured between the thermal solar module and the photovoltaic module, the amorphous material having a semi-viscous, thermally conductive, and mastic characteristic to allow for thermal expansion and contraction of either or both the photovoltaic module or the solar thermal module during an operating time; and
an aperture region provided on a first side of the photovoltaic module and the solar thermal module is overlying a second side of the photovoltaic module;
whereupon the thermal solar module, the photovoltaic module, and the amorphous material form an integrated thermal solar module.

15. Apparatus of claim 14 further comprising a frame structure configured to the photovoltaic module; or wherein the thermal solar module is free from a frame assembly and comprises exposed edges.

16. Apparatus of claim 14 further comprising a plurality of tubes configured within the thermal solar module.

17. Apparatus of claim 14 wherein the amorphous material is characterized by high thermal stability and resistance to separation as proven by over 168 hours at 85 degrees-Celsius, low volatile content maintaining greater than 98% solids by weight over 168 continuous hours at 85 degrees-Celsius, weather resistant as proven by exposure to damp heat at 85% relative humidity and 85 degrees-Celsius, high thermal conductivity with values in excess of 0.6 joule/(m)(s)(Degree K), and a high surface tension and viscosity as proven by a slump test with 2 inch diameter sample pressed against a vertically oriented plate wherein the sample falls less than ⅜ inch over 30 minute period.

18. Apparatus of claim 14 wherein the operating time is provided of at least twenty years or more without delamination or other failure mode.

19. Apparatus of claim 14 wherein the amorphous material comprises a non-volatile hydrocarbon entity, a plurality of particles, and a plurality of surfactants to cause the thickness of material to be substantially homogeneous; and further comprising a frame assembly and the thermal solar module comprises an adhesive material configured to exceed 30 pounds per square inch in shear strength over a twenty year operation life; wherein the thermal solar module photovoltaic module has a width of forty eight inches and greater and a width length of one hundred inches and greater.

20. Apparatus of claim 14 wherein the thermal solar module photovoltaic module has a weight of 0.5 pounds per square foot and less; and wherein the plurality of solar cells are electrically strung together in series such that no interconnects interfere with a lengthwise thermal expansion of the photovoltaic module; wherein the plurality of solar cells are electrically strung together in series such that a resulting maximum power voltage ranges from 90 to 110 volts; wherein the polymeric material comprises ETFE, EVA, PET, and EVA; and further comprising a frame assembly configured to the integrated thermal solar module with a unique attribute of elevation above the roof structure, mounting to all common roof structures, minimal roof penetrations, aligning to standard structural members, avoiding debris accumulation, providing for a high degree of movement to prevent damage caused by constrained thermal expansion.
